(19) United States
(12) Patent Application Publication
(10) Pub. No.: US 2009/0121229 A1
(43) Pub. Date: May 14, 2009

(54) Display device

(75) Inventors: Terunori Saitou, Mobara (JP); Yoshiharu Owaku, Mobara (JP); Toshio Miyazawa, Chiba (JP)

Correspondence Address: Stanley P. Fisher;Reed Smith LLP, Suite 1400, 3110 Fairview Park Drive, Falls Church, VA, 22042-4503, US

(73) Assignee: Hitachi Displays, Ltd.

(21) Appl. No.: 12/292,090

(22) Filed: Nov. 12, 2008

(30) Foreign Application Priority Data
Nov. 14, 2007 (JP) 2007-295826

(51) Int. Cl. H01L 27/088

(52) U.S. Cl. 257/59; 257/E27.06

(57) ABSTRACT

In a display device which includes: an insulation substrate; thin film transistors which are formed on the insulation substrate; and terminal portions which are configured to supply voltages to the thin film transistors, the thin film transistor includes a gate electrode and a gate line which is formed of a material equal to a material of the gate electrode, a metal line is connected to the terminal portion, a first insulation film and a second insulation film which is made of a material different from a material of the first insulation film are sequentially stacked on the gate line, an opening which exposes the gate line is formed in the first insulation film and the second insulation film, a side wall surface of the opening is sequentially covered with a protective film, a first transparent conductive film and a third insulation film, the first transparent conductive film and a second transparent conductive film are sequentially stacked on an exposed portion of the gate line, and the second transparent conductive film is connected with the metal line.

The present application claims priority from Japanese applications JP2007-295826 filed on Nov. 14, 2007, the content of which is hereby incorporated by reference into this application.

### BACKGROUND OF THE INVENTION

1. Field of the Invention

The present invention relates to a display device including thin film transistors, and more particularly to a display device which can enhance the reliability of the connection between the thin film transistors and terminals.

2. Description of the Related Art

In a display device which forms thin film transistors on an insulation substrate, gate electrodes of the thin film transistors and gate lines which are led out from the gate electrodes are made of a molybdenum-tungsten (Mo—W) alloy, for example, from a viewpoint of ensuring characteristics of the thin film transistor. On the other hand, a terminal portion which is formed on an end portion of the insulation substrate and metal lines which are led out from the terminal portion are made of aluminum or an aluminum alloy from a viewpoint of reducing the line resistance. The connection between the gate line and the metal line which is led out from the terminal portion is established by way of a conductive film which is continuously formed between a contact hole formed in the gate line and a contact hole formed in the metal line.

Further, an insulation film which is formed above the gate electrodes and the gate lines of the thin film transistor, particularly, the inversely-staggered-type (bottom-gate-type) thin film transistor is a multi-layered film which is formed by stacking insulation films made of different materials from a viewpoint of ensuring the electric characteristic of the thin film transistor. The multi-layered film is also formed on a side wall surface of the contact hole formed in the gate line. The respective insulation films of the multi-layered film being made of differ materials from each other implies that the respective insulation films exhibit different etching rates. Accordingly, in performing etching for forming the contact hole, the degree of etching differs among the respective insulation films and hence, a stepped portion attributed to unevenness is formed on the side wall surface of the contact hole. When the uneven stepped portion exists on the side wall surface of the contact hole, it becomes difficult to ensure the electrical conduction via the contact hole. Accordingly, the reliability of the connection between the gate line and the metal line led out from the terminal portion is lowered.

As a related art on a display device which uses an inversely-staggered-type thin film transistor, JP-A-5-55570 (patent document 1) discloses a display device which adopts, as thin film transistors which are arranged on a back-surface substrate side thereof, a first thin film transistor of inversely-staggered structure in which a channel region is formed of the stacked structure formed of a polycrystalline silicon layer and an amorphous silicon layer, and a second thin film transistor of inversely-staggered structure in which a channel region is formed of the single-layered amorphous silicon structure.

### SUMMARY OF THE INVENTION

In the above-mentioned constitution of the related art, due to the above-mentioned constitution of the insulation film, there exists a possibility that a stepped portion consisting of concaves and convexes is formed on the side wall surface of the contact hole which is opened in and arranged on the gate line. Such a stepped portion causes the disconnection of lines or conductive films which are formed on an upper layer of the contact hole thus giving rise to a drawback that the electrical conduction cannot be ensured. To overcome this drawback, a method which flattens the side wall surface of the contact hole by performing optimal etching for respective insulation films may be considered. However, this method increases man-hours such as an addition of a photolithographic step, or makes the processing complicated and hence, the productivity of the display device is reduced thus becoming one of causes which obstruct lowering of a manufacturing cost of the display device.

Accordingly, it is an object of the present invention to provide a display device which can prevent the formation of a stepped portion on a side wall surface of a contact hole formed in a gate line attributed to unevenness of the side wall surface and can ensure the reliability of the electrical conduction between a gate line and a metal line led out from a terminal portion thus realizing an image display of high-quality.

To briefly explain typical inventions among inventions disclosed in this specification, they are as follows.

(1) The present invention is directed to a display device which includes: an insulation substrate; thin film transistors which are formed on the insulation substrate; and a terminal portion which is configured to supply voltages to the thin film transistors, wherein the thin film transistor includes a gate electrode and a gate line which is formed of a material equal to a material of the gate electrode, a metal line is connected to the terminal portion, a first insulation film and a second insulation film which is made of a material different from a material of the first insulation film are sequentially stacked on the gate line, an opening which exposes the gate line is formed in the first insulation film and the second insulation film,

a side wall surface of the opening is sequentially covered with a protective film, a first transparent conductive film and a third insulation film, the first transparent conductive film and a second transparent conductive film are sequentially stacked on an exposed portion of the gate line, and the second transparent conductive film is connected with the metal line.

(2) In the display device having the constitution (1), either one of the first insulation film and the second insulation film may be formed of a silicon oxide film and another insulation film may be formed of a silicon nitride film.

(3) In the display device having the constitution (1) or (2), the gate line is made of metal selected from a group of metals consisting of chromium, molybdenum, tungsten, titanium and an alloy containing any metal selected from the group of metals.

(4) In the display device having any one of the constitutions (1) to (3), the metal line is made of aluminum or an aluminum alloy containing aluminum as a main component.

(5) In the display device having any one of the constitutions (1) to (4), a semiconductor layer of the thin film transistor is formed of a polysilicon layer or a stacked body which is constituted of a polysilicon layer and an amorphous silicon layer formed on the polysilicon layer.

(6) In the display device having any one of the constitutions (1) to (5), the display device includes a counter substrate which is bonded to the insulation substrate with a predetermined gap therebetween, and a liquid crystal layer which is held in the gap, pixel electrodes and counter electrodes which are configured to apply voltages to the liquid crystal layer are formed on the insulation substrate, and the first transparent conductive film is formed on the same layer as the counter electrodes.

(7) In the display device having any one of the constitutions (1) to (6), the insulation substrate includes a display region and a peripheral region which surrounds the display region, a drive circuit is formed on the peripheral region, and the thin film transistor forms a constitutional element of the drive circuit.

According to the present invention, the opening is formed by etching the insulation films of the stacked film having the different etching rates formed on the gate line simultaneously under conditions suitable for the respective insulation films. Due to such constitution, it is unnecessary to add a photolithography step to a manufacturing process of the display device, and the manufacturing process of the display device can be simplified and hence, a manufacturing cost of the display device can be lowered. Further, the unevenness of the side wall surface of the contact hole can be reduced by forming the multi-layered film in the contact hole and hence, it is possible to ensure the reliability of the connection between the gate line and the metal line led out from the terminal portion.

Here, the present invention is not limited to a liquid crystal display device and is applicable to an organic EL display device and is applicable to various kinds of so-called active-drive-type display devices.

### BRIEF DESCRIPTION OF THE DRAWING

FIG. 1A and FIG. 1B are schematic views showing one embodiment of a display device according to the present invention, wherein FIG. 1A is a side view of the display device and FIG. 1B is a plan view of the display device shown in FIG. 1A;

FIG. 2 is a schematic cross-sectional view of an essential part of the display device shown in FIG. 1B;

FIG. 3A and FIG. 3B are views showing steps for explaining a manufacturing method of the display device according to the present invention, wherein FIG. 3A is a schematic plan view, and FIG. 3B is a schematic cross-sectional view taken along a line A-A in FIG. 3A;

FIG. 4A and FIG. 4B are views showing steps for explaining a manufacturing method of the display device according to the present invention, wherein FIG. 4A is a schematic plan view, and FIG. 4B is a schematic cross-sectional view taken along a line A-A in FIG. 4A;

FIG. 5A and FIG. 5B are views showing steps for explaining a manufacturing method of the display device according to the present invention, wherein FIG. 5A is a schematic plan view, and FIG. 5B is a schematic cross-sectional view taken along a line A-A in FIG. 5A;

FIG. 6A and FIG. 6B are views showing steps for explaining a manufacturing method of the display device according to the present invention, wherein FIG. 6A is a schematic plan view, and FIG. 6B is a schematic cross-sectional view taken along a line A-A in FIG. 6A;

FIG. 7A and FIG. 7B are views showing steps for explaining a manufacturing method of the display device according to the present invention, wherein FIG. 7A is a schematic plan view, and FIG. 7B is a schematic cross-sectional view taken along a line A-A in FIG. 7A;

FIG. 8A and FIG. 8B are views showing steps for explaining a manufacturing method of the display device according to the present invention, wherein FIG. 8A is a schematic plan view, and FIG. 8B is a schematic cross-sectional view taken along a line A-A in FIG. 8A;

FIG. 9A and FIG. 9B are views showing steps for explaining a manufacturing method of the display device according to the present invention, wherein FIG. 9A is a schematic plan view, and FIG. 9B is a schematic cross-sectional view taken along a line A-A in FIG. 9A;

FIG. 10A and FIG. 10B are views showing steps for explaining a manufacturing method of the display device according to the present invention, wherein FIG. 10A is a schematic plan view, and FIG. 10B is a schematic cross-sectional view taken along a line A-A in FIG. 10A;

FIG. 11A and FIG. 11B are views showing steps for explaining a manufacturing method of the display device according to the present invention, wherein FIG. 11A is a schematic plan view, and FIG. 11B is a schematic cross-sectional view taken along a line A-A in FIG. 11A;

FIG. 12A and FIG. 12B are views showing steps for explaining a manufacturing method of the display device according to the present invention, wherein FIG. 12A is a schematic plan view, and FIG. 12B is a schematic cross-sectional view taken along a line A-A in FIG. 12A;

FIG. 13A and FIG. 13B are views showing steps for explaining a manufacturing method of the display device according to the present invention, wherein FIG. 13A is a schematic plan view, and FIG. 13B is a schematic cross-sectional view taken along a line A-A in FIG. 13A;

FIG. 14A and FIG. 14B are views showing steps for explaining a manufacturing method of the display device according to the present invention, wherein FIG. 14A is a schematic plan view, and FIG. 14B is a schematic cross-sectional view taken along a line A-A in FIG. 14A;

FIG. 15A and FIG. 15B are views showing steps for explaining a manufacturing method of the display device according to the present invention, wherein FIG. 15A is a schematic plan view, and FIG. 15B is a schematic cross-sectional view taken along a line A-A in FIG. 15A;

FIG. 16A and FIG. 16B are views showing steps for explaining a manufacturing method of the display device according to the present invention, wherein FIG. 16A is a schematic plan view, and FIG. 16B is a schematic cross-sectional view taken along a line A-A in FIG. 16A;

FIG. 17A and FIG. 17B are views showing steps for explaining a manufacturing method of the display device according to the present invention, wherein FIG. 17A is a schematic plan view, and FIG. 17B is a schematic cross-sectional view taken along a line A-A in FIG. 17A;

FIG. 18A and FIG. 18B are views showing steps for explaining a manufacturing method of the display device according to the present invention, wherein FIG. 18A is a schematic plan view, and FIG. 18B is a schematic cross-sectional view taken along a line A-A in FIG. 18A;

FIG. 19A and FIG. 19B are views showing steps for explaining a manufacturing method of the display device according to the present invention, wherein FIG. 19A is a schematic plan view, and FIG. 19B is a schematic cross-sectional view taken along a line A-A in FIG. 19A;

FIG. 20A and FIG. 20B are views showing steps for explaining a manufacturing method of the display device according to the present invention, wherein FIG. 20A is a schematic plan view, and FIG. 20B is a schematic cross-sectional view taken along a line A-A in FIG. 20A;

FIG. 21A and FIG. 21B are views showing steps for explaining a manufacturing method of the display device according to the present invention, wherein FIG. 21A is a schematic plan view, and FIG. 21B is a schematic cross-sectional view taken along a line A-A in FIG. 21A; and

FIG. 22A and FIG. 22B are views showing steps for explaining a manufacturing method of the display device according to the present invention, wherein FIG. 22A is a schematic plan view, and FIG. 22B is a schematic cross-sectional view taken along a line A-A in FIG. 22A.

### DESCRIPTION OF THE PREFERRED EMBODIMENTS

Hereinafter, a best mode for carrying out a display device of the present invention is explained in detail in conjunction with embodiments by reference to drawings which show the embodiments.

### Embodiment 1

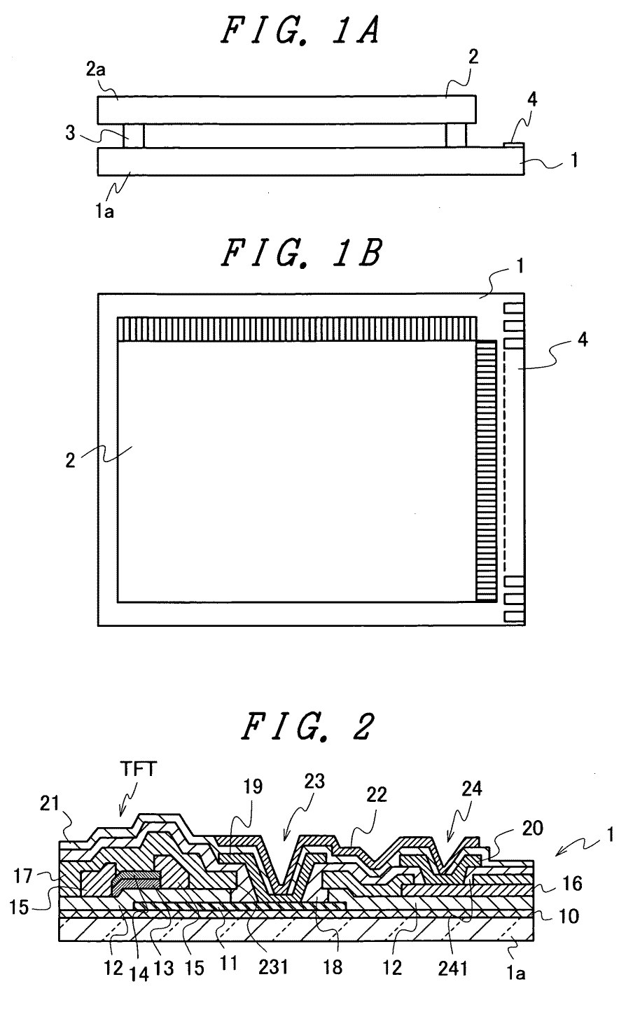

FIG. 1A and FIG. 1B are views for explaining an embodiment 1 of a display device according to the present invention, wherein FIG. 1A is a schematic side view of the display device, and FIG. 1B is a schematic plan view of the display device shown in FIG. 1A. In FIG. 1A and FIG. 1B, numeral 1 indicates a back substrate including an insulation substrate 1a such as a glass plate. The back substrate 1 is constituted such that thin film transistors of inversely staggered structure, counter electrodes (common electrodes), a terminal portion which is connected with the thin film transistors and the like are formed on the insulation substrate 1a. Here, each thin film transistor has a channel region which is formed of a polysilicon film or the stacked structure consisting of a polysilicon film and an amorphous silicon film. Numeral 2 indicates a face substrate including a transparent plate 2a such as a glass plate. The face substrate 2 is arranged to face the back substrate 1 in an opposed manner. Numeral 3 indicates a sealing material, and the sealing material 3 is hermetically arranged between the back substrate 1 and the face substrate 2 and surrounds a liquid crystal layer which is arranged between the back substrate 1 and the face substrate 2, for example. Numeral 4 indicates a terminal portion. Metal lines which are led out from the terminal portion 4 are connected with gate lines of the thin film transistors or the like. The terminal portion 4 is formed on one end surface or a plurality of end surfaces of the back substrate 1.

FIG. 2 is a schematic cross-sectional view of an essential part of the back substrate 1. FIG. 2 shows a cross section of the display device including the thin film transistors TFT1 shown in FIG. 1B, wherein parts identical with the parts shown in FIG. 1 are given same numerals. In FIG. 2, on a surface of the insulation substrate 1a, a background barrier film 10 is formed, and gate electrodes and gate lines 11, a first insulation film 12, a polysilicon layer 13, an amorphous silicon layer 14, source and drain electrodes 15, the metal lines 16 led out from the terminal portion 4, a second insulation film 17, an organic protective film 18, first transparent conductive films 19, 20, a third insulation film 21, a second transparent conductive film 22 and the like are stacked or arranged parallel to each other. Further, numeral 23 indicates a first contact hole, and numeral 24 indicates a second contact hole.

In FIG. 2, the first contact hole 23 which is arranged on the gate line 11 includes an opening 231 which penetrates an insulation film arranged on the gate line 11 in a stacked manner. Here, the insulation film is formed of, for example, a stacked film consisting of the first insulation film 12 formed of a SiO₂ film and constitutes a gate insulation film and the second insulation film 17 which is formed of a SiN film and has an etching rate different from an etching rate of the first insulation film 12, and the opening penetrates these first and second insulation films 12, 17 substantially coaxially. At a point of time that the formation of the opening 231 is completed, on a boundary portion between the first insulation film 12 and the second insulation film 17 on a side wall surface of the opening 231, a stepped portion attributed to the difference in etching rate is present. Further, the second contact hole 24 includes an opening 241 which penetrates the second insulation film 17. A side wall surface of the opening 241 is formed substantially smoothly. These openings 231, 241 are formed in the same step.

First of all, the opening 231 which constitutes the first contact hole 23 includes the organic protective film 18 which covers a region ranging from a bottom surface of the opening 231 which is brought into contact with a surface of the gate line 11 to a portion of the second insulation film 17 by way of the side wall surface and a top surface of the opening 231. With such an organic protective film 18, lowering of the reliability of electrical connection attributed to the stepped portion on the side wall surface is not yet eliminated.

Next, the first transparent conductive film 19 made of ITO, for example, is arranged in a state that the first transparent conductive film 19 covers the organic protective film 18 in the inside of the opening 231. The first transparent conductive film 19 has one end side thereof made electrically conductive with the gate line 11 on the bottom surface of the opening 231 and has another end thereof extended in the direction toward the top surface of the opening 231 so as to cover a portion of the organic protective film 18.

On the other hand, the first transparent conductive film 20 is formed in the second contact hole 24 in a state that the first transparent conductive film 20 covers the organic protective film 18 formed in the inside of the opening 241. The first transparent conductive film 20 is formed simultaneously with the first transparent conductive film 19. The first transparent conductive film 20 has one end side thereof made electrically conductive with the metal line 16 on a bottom surface of the opening 241 and has another end thereof extended in the direction toward a top surface of the opening 241 so as to cover a portion of the organic protective film 18.

Further, the surfaces of the first transparent conductive films 19, 20 are covered with the third insulation film 21 formed of a SiN film, for example, except for portions of the bottom surfaces of the transparent conductive films 19, 20. Further, on respective portions of the bottom surfaces of the transparent conductive films 19, 20 which are exposed from the third insulation film 21, the continuous second transparent conductive film 22 which is brought into contact with the first transparent conductive films 19, 20 respectively and makes the first transparent conductive films 19, 20 electrically conductive with each other is arranged by stacking. The second transparent conductive film 22 is formed of an ITO film, for example.

Due to such constitution, with the use of the continuous second transparent conductive film 22 which is brought into contact with the first transparent conductive film 19 in the inside of the first contact hole 23 and the first transparent conductive film 20 in the inside of the second contact hole 24, the gate electrode 11 and the lead terminal 16 are connected with each other in an electrically conductive manner.

As described above, by covering the stepped portion which is formed on the opening 231 of the first contact hole 23 with the first transparent conductive film 19 and the third insulation film 21, the stepped portion can be eliminated and hence, it is possible to prevent the disconnection of the second transparent conductive film 22 thus enhancing the reliability of electrical connection.

Here, the thin film transistor having the above-mentioned constitution may be used as a thin film transistor which constitutes a pixel in a display region of the display device. Further, the thin film transistor having the above-mentioned constitution may be used as a thin film transistor which constitutes a drive circuit in a peripheral region which surrounds the display region.

### Embodiment 2

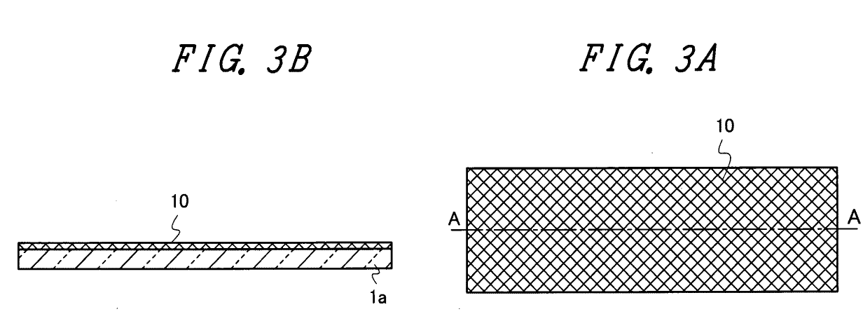

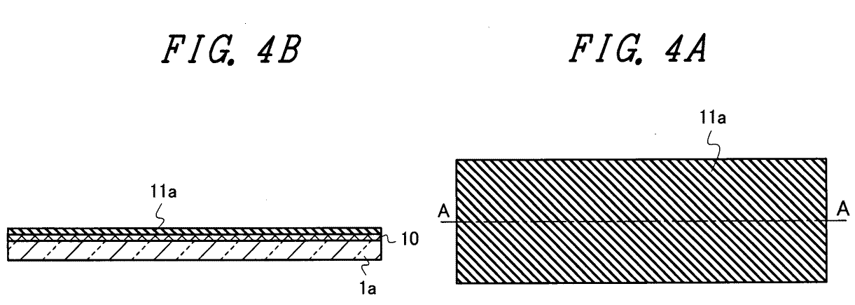

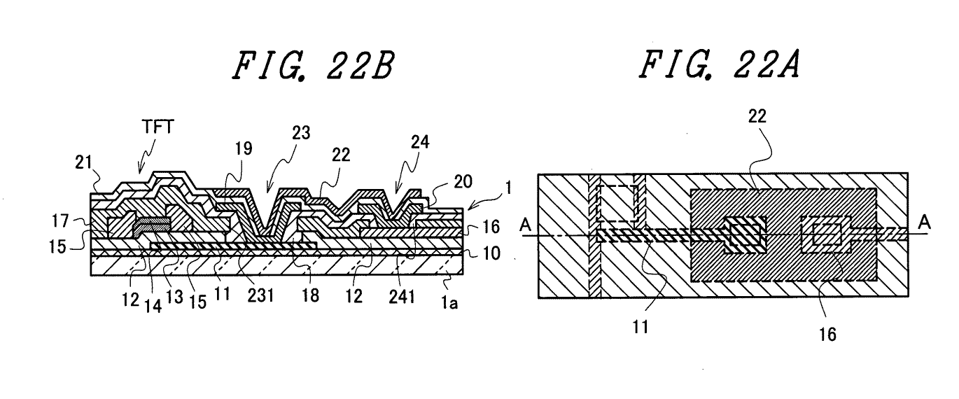

Next, an embodiment of a manufacturing method of the display device according to the present invention is explained as an embodiment 2. FIG. 3A to FIG. 22B are views showing steps for explaining the manufacturing method of the display device according to the present invention. In all drawings, FIG. 3A, FIG. 4A, . . . , and FIG. 22A are schematic plan views, and FIG. 3B, FIG. 4B, . . . , and FIG. 22B are cross-sectional views taken along a line A-A in FIG. 3A, FIG. 4A, . . . , and FIG. 22A. Here, in the respective drawings, parts identical with the parts described previously are given same numerals. Hereinafter, the manufacturing method of the display device of the present invention is explained in conjunction with FIG. 3A to FIG. 22B. In the explanation made hereinafter, particularly, an embodiment of a portion corresponding to a portion in FIG. 2 is explained.

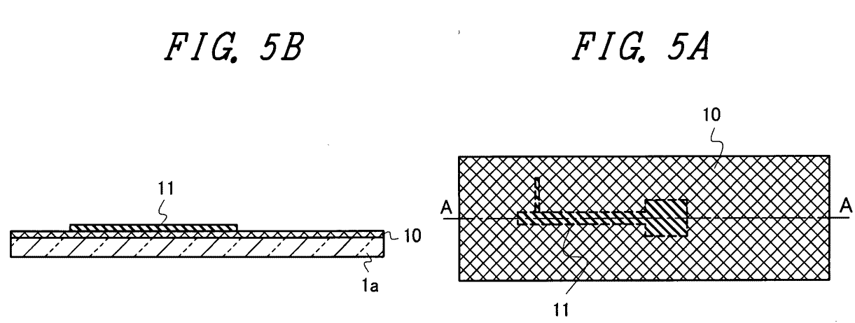

First of all, as shown in FIG. 3A and FIG. 3B, an insulation substrate 1a is covered with a background barrier film 10. The background barrier film 10 is not indispensable. Next, a gate electrode film 11a which constitutes gate electrodes and gate lines 11 is formed on the background barrier film 10 by sputtering as shown in FIG. 4A and FIG. 4B. By exposing the gate electrode film 11a by way of a photo mask and, thereafter, by developing exposed portions, the gate electrodes and the gate lines 11 are formed as shown in FIG. 5A and FIG. 5B. As an electrode film material, chromium, molybdenum, tungsten, titanium or an alloy containing any one of these materials may be used, for example.

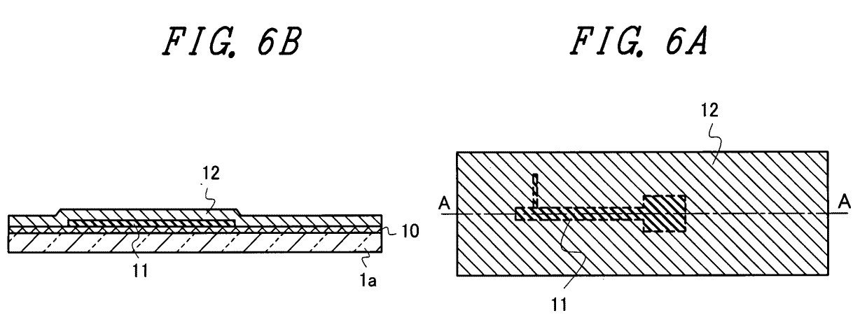

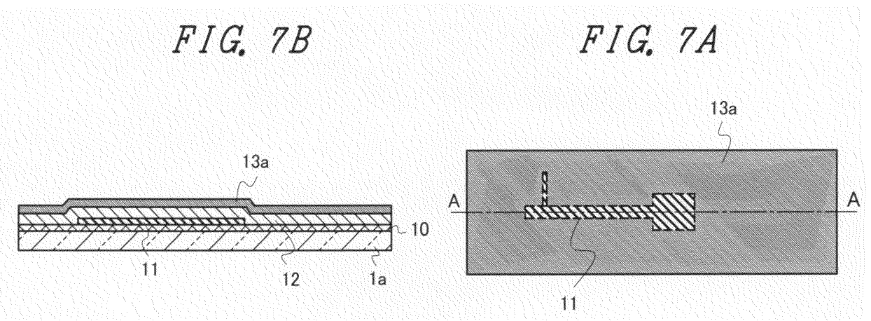

Then, as shown in FIG. 6A and FIG. 6B, a surface of the insulation substrate 1a including the gate lines 11 is covered with a first insulation film 12. The first insulation film 12 is formed of a SiO₂ (silicon oxide) film and constitutes a gate insulation film. Next, for forming a polysilicon layer 13, an amorphous silicon (a-Si) layer 13a is formed as shown in FIG. 7A and FIG. 7B. A film forming method is a plasma CVD method, for example.

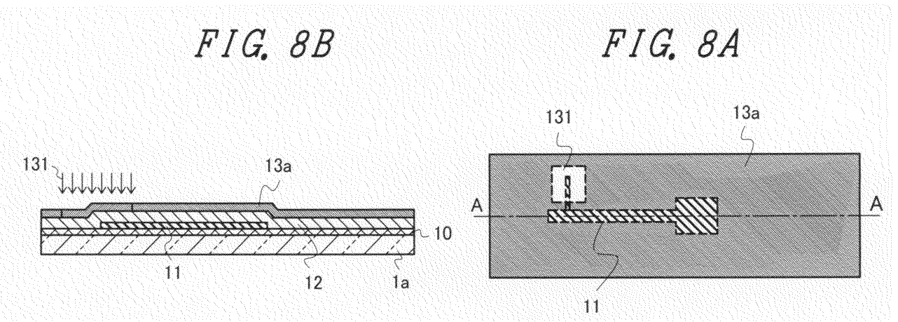

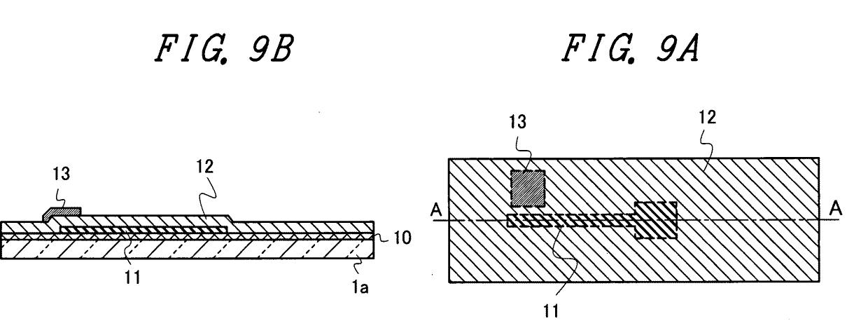

Next, as shown in FIG. 8A and FIG. 8B, laser beams 131 are radiated to a portion of the amorphous silicon (a-Si) layer 13a which corresponds to the gate electrode thus forming the polysilicon layer 13 on the beam radiated portion and the amorphous silicon (a-Si) layer 13a on a remaining portion is removed (see FIG. 9A and FIG. 9B) For example, excimer lasers may be used as the laser beams to be radiated.

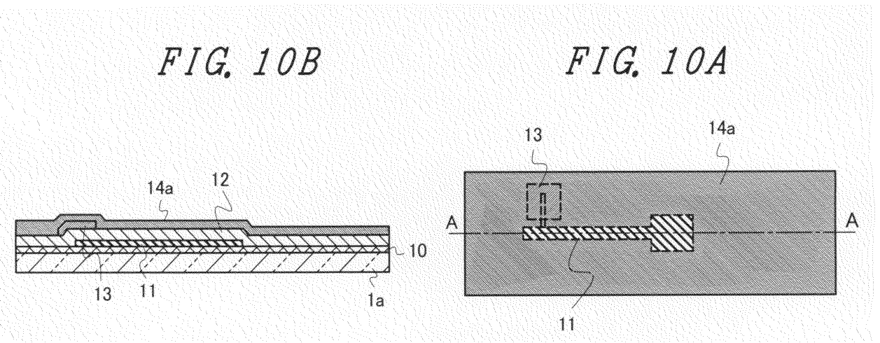

Next, to form an amorphous silicon layer 14, as shown in FIG. 10A and FIG. 10B, an amorphous silicon (a-Si) layer 14a is formed on the surface of the insulation substrate 1a including the polysilicon layer 13.

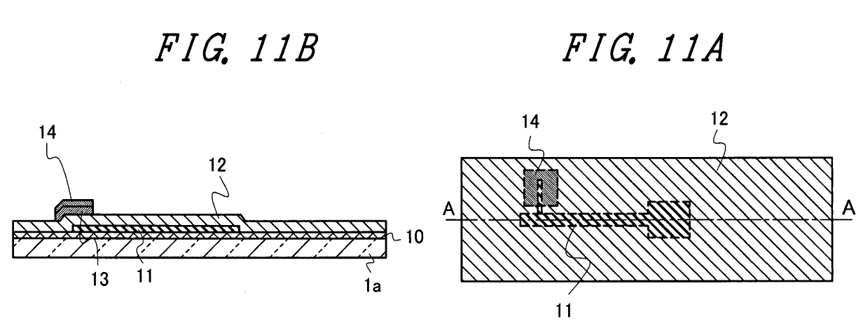

Next, the amorphous silicon (a-Si) layer 14a is exposed by way a photo mask, the above-mentioned amorphous silicon layer 14 is formed on the polysilicon layer 13 in a stacked manner by etching, and the amorphous silicon (a-Si) layer 14a on a remaining portion is removed (see FIG. 11A and FIG. 11B). A semiconductor layer of a thin film transistor may have the single-layered structure made of a polysilicon layer.

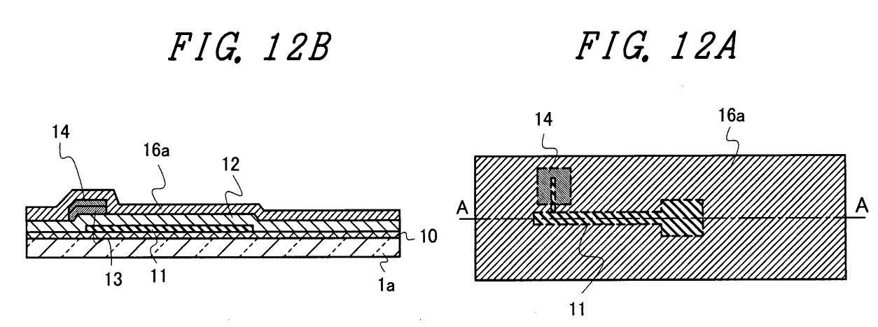

Next, an aluminum film 16a which is used for forming source and drain electrodes 15 and lead terminals 16 is formed on the surface of the insulation substrate 1a including the amorphous silicon layer 14 by sputtering as shown in FIG. 12A and FIG. 12B. The aluminum film 16a may be formed using an aluminum alloy containing aluminum as a main component.

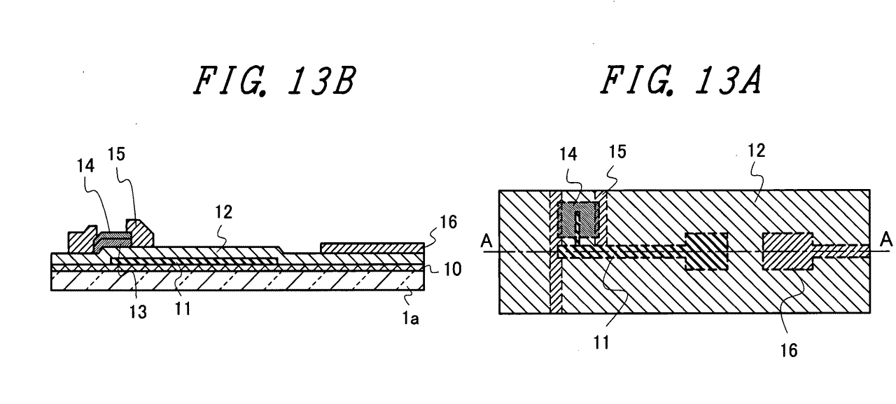

Next, the aluminum film 16a is processed so as to form the source and drain electrodes 15 and metal lines 16 led out from terminal portions. In such a process, as shown in FIG. 13A and FIG. 13B, the source and drain electrodes 15 are formed at a position where the gate electrode is sandwiched in a state that the source and drain electrodes 15 are in contact with the amorphous silicon layer 14, the metal lines 16 have one ends thereof arranged adjacent to end portions of the gate lines 11 and another ends thereof extended to an end surface of the insulation substrate 1a, that is, to an terminal portion 4 shown in FIG. 1A and FIG. 1B.

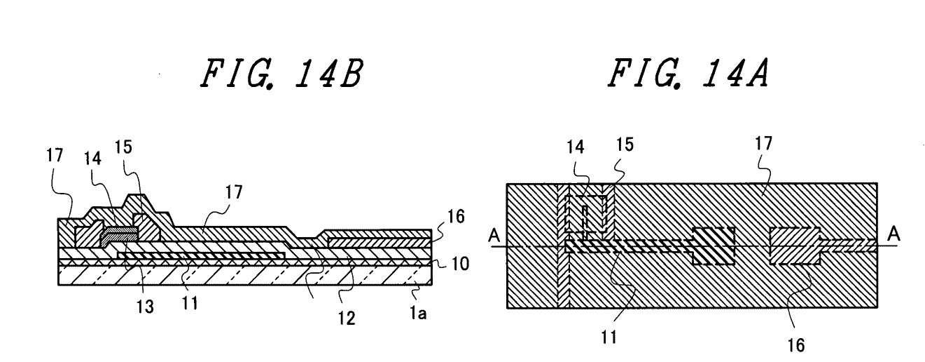

Next, as shown in FIG. 14A and FIG. 14B, the surface of the insulation substrate 1a including the electrodes 15 and the lead terminals 16 is covered with a second insulation film 17. The second insulation film 17 is formed of an insulation film such as a SiN (silicon nitride) film.

Next, first contact holes 23 and second contact holes 24 are respectively formed above the gate lines 11 and the metal lines 16. In forming the first and second contact holes 23 and 24, on the gate line 11 side, first of all, the first contact hole 23 is formed by forming an opening 231 in a stacked film consisting of the first and second insulation films 12, 17 by etching. On the other hand, on the metal line 16 side, the second contact hole 24 is formed by forming an opening 241 in the second insulation film 17 by etching. These openings 231, 241 are formed in the same step.

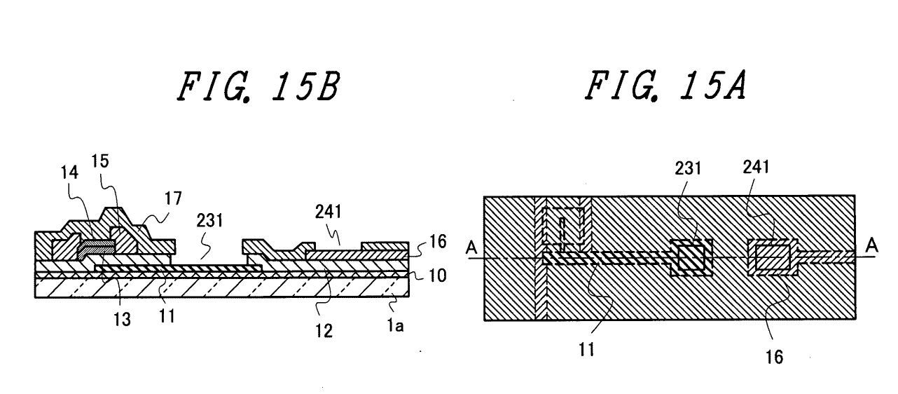

This etching is performed under an etching condition suitable for the second insulation film 17 (SiN film in this embodiment). Due to such etching, the first insulation film 12 is over-etched thus forming a stepped portion on a side wall surface of the opening 231 (see FIG. 15A and FIG. 15B).

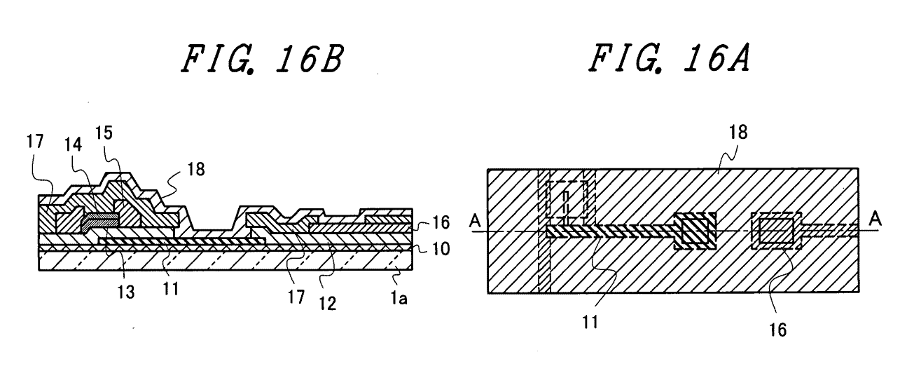

Next, the surface of the insulation substrate 1a including the side wall surfaces of the openings 231, 241 is covered with an organic protective film 18 (see FIG. 16A and FIG. 16B).

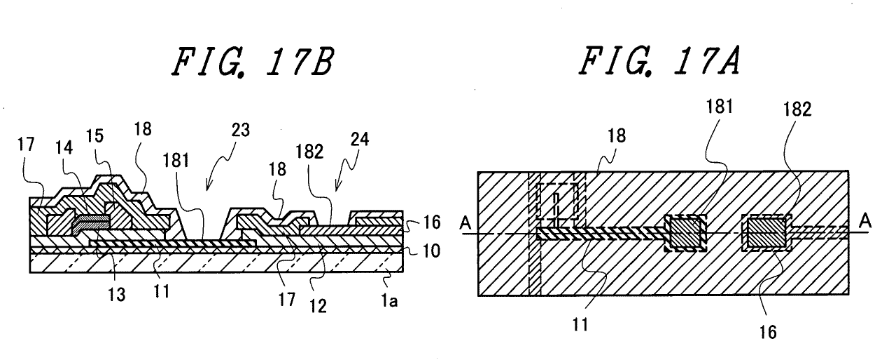

Next, the organic protective film 18 is formed so as to form holes 181, 182 of sizes sufficient to expose a portion of the gate line 11 and a portion of the metal line 16 respectively in respective bottom surfaces of the openings 231, 241 (see FIG. 17A and FIG. 17B).

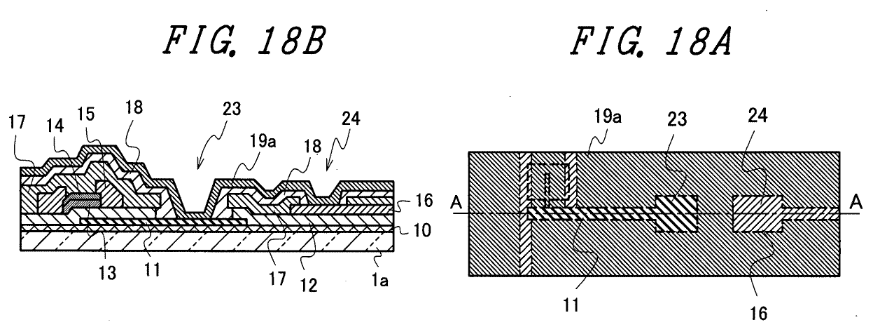

Next, a transparent conductive film 19a is formed on the insulation substrate 1a in a state that the organic protective film 18 is covered with the transparent conductive film 19a. The transparent conductive film 19a is formed of an ITO film. The transparent conductive film 19a is configured to be conductive with the gate line 11 and the metal line 16 respectively at the above-mentioned hole 181, 182 portions as shown in FIG. 18A and FIG. 18B.

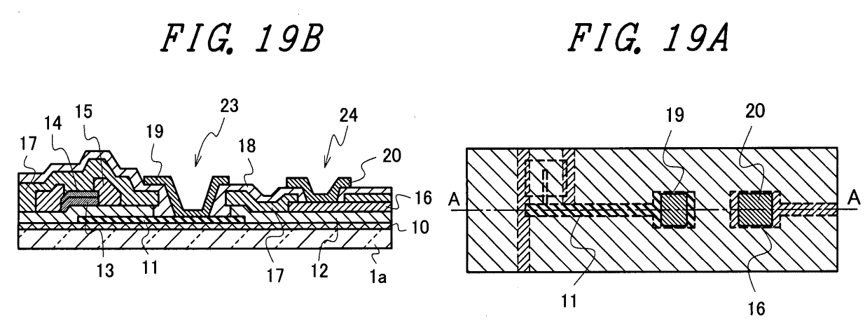

Next, the transparent conductive film 19a is formed such that, as shown in FIG. 19A and FIG. 19B, a first transparent conductive film 19 having an approximately U-shaped cross section is formed in the opening 231, and a first transparent conductive film 20 having an approximately U-shaped cross section is formed in the opening 241. The transparent conductive film 19a on the remaining portion is removed. With respect to a display device which forms pixel electrodes and counter electrodes on the insulation substrate 1a, using the transparent conductive film 19a, either one of the counter electrodes or the pixel electrodes may be formed simultaneously with the formation of the first transparent conductive films 19, 20.

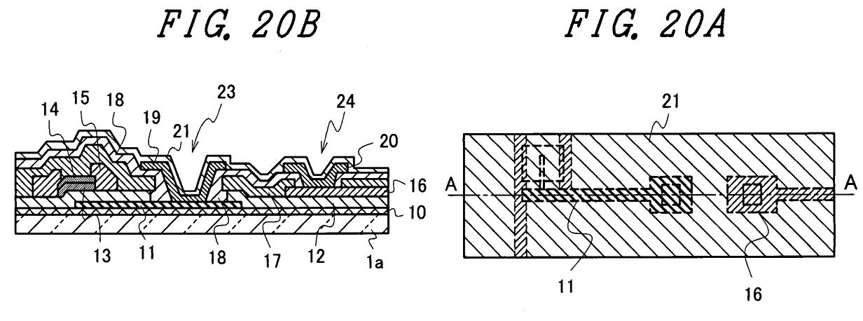

Next, the surface of the insulation substrate 1a including the first transparent conductive film 19, 20 is covered with a third insulation film 21. The third insulation film 21 is formed of an insulation film such as a SiN (silicon nitride) film (see FIG. 20A and FIG. 20B).

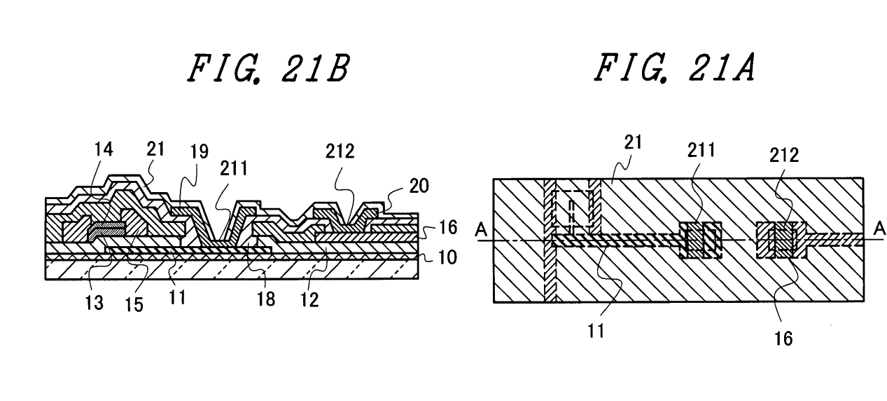

Next, the third insulation film 21 is formed so as to form holes 211, 212 of sizes sufficient to expose a portion of the first transparent conductive film 19 and a portion of the first transparent conductive film 20 respectively in respective bottom surfaces of the openings 231, 241 in the contact hole 23, 24(see FIG. 21A and FIG. 21B).

Next, a second transparent conductive film 22 is formed on the insulation substrate 1a in a state that a portion of the third insulation film 21 in a range from the contact hole 23 to the contact hole 24 is continuously covered with the second transparent conductive film 22. The second transparent conductive film 22 is formed of an ITO film (see FIG. 22A and FIG. 22B). The second conductive film 22 is, as shown in FIG. 22A and FIG. 22B, made conductive with the first transparent conductive films 19, 20 at the above-mentioned hole 211, 212 portions respectively. Including such electrical conduction, the gate line 11 and the metal line 16 are connected with each other by a path constituted of the gate line 11, the first transparent conductive film 19, the second transparent conductive film 22, the first transparent conductive film 20 and the metal line 16.

Due to such constitution, the formation of the stepped portion in the contact hole attributed to the difference in etching rate can be eliminated without deteriorating the mass productivity and hence, it is possible to provide a display device which can realize an image display of high quality and a manufacturing method of the display device.

What is claimed is:

1. A display device comprising:
an insulation substrate;
thin film transistors which are formed on the insulation substrate; and
terminal portions which are configured to supply voltages to the thin film transistors, wherein
the thin film transistor includes a gate electrode and a gate line which is formed of a material equal to a material of the gate electrode,
a metal line is connected to the terminal portion,
a first insulation film and a second insulation film which is made of a material different from a material of the first insulation film are sequentially stacked on the gate line,
an opening which exposes the gate line is formed in the first insulation film and the second insulation film,
a side wall surface of the opening is sequentially covered with a protective film, a first transparent conductive film and a third insulation film,
the first transparent conductive film and a second transparent conductive film are sequentially stacked on an exposed portion of the gate line, and
the second transparent conductive film is connected with the metal line.

2. A display device according to claim 1, wherein either one of the first insulation film and the second insulation film is formed of a silicon oxide film and another insulation film is formed of a silicon nitride film.

3. A display device according to claim 1, wherein the gate line is made of metal selected from a group of metals consisting of chromium, molybdenum, tungsten, titanium and an alloy containing any metal selected from the group of metals.

4. A display device according to claim 1, wherein the metal line is made of aluminum or an aluminum alloy containing aluminum as a main component.

5. A display device according to claim 1, wherein a semiconductor layer of the thin film transistor is formed of a polysilicon layer or a stacked body which is constituted of a polysilicon layer and an amorphous silicon layer formed on the polysilicon layer.

6. A display device according to claim 1, wherein the display device includes a counter substrate which is bonded to the insulation substrate with a predetermined gap therebetween, and a liquid crystal layer which is held in the gap,
pixel electrodes and counter electrodes which are configured to apply voltages to the liquid crystal layer are formed on the insulation substrate, and
the first transparent conductive film is formed on the same layer as the counter electrodes.

7. A display device according to claim 1, wherein the insulation substrate includes a display region and a peripheral region which surrounds the display region,
a drive circuit is formed on the peripheral region, and
the thin film transistor forms a constitutional element of the drive circuit.
